(19) United States
(12) Patent Application Publication
(10) Pub. No.: US 2014/0299941 A1
(43) Pub. Date: Oct. 9, 2014

(54) SRAM CELL WITH REDUCED VOLTAGE DROOP

(71) Applicant: GLOBALFOUNDRIES Inc., (US)

(72) Inventor: Bipul C. Paul, Clifton Park, NY (US)

(73) Assignee: GLOBALFOUNDRIES Inc., Grand Cayman (KY)

(21) Appl. No.: 13/856,548

(22) Filed: Apr. 4, 2013

(51) Int. Cl. H01L 27/11

(52) U.S. Cl. CPC H01L 27/1104
USPC 257/401

(57) ABSTRACT

A mesh circuit for the VSS supply voltage of a SRAM device is disclosed. Embodiments also provide a SRAM bitcell design comprising a VSS mesh disposed in two different metal layers. One metal layer includes horizontal VSS lines, while another metal layer includes vertical VSS lines. A via layer disposed between the first metal layer and second metal layer connects the two metal layers together.

### FIELD OF THE INVENTION

The present invention relates generally to semiconductor fabrication and, more particularly, to improvements in SRAM wiring arrangements.

### BACKGROUND

Static random access memory (SRAM) is commonly used in integrated circuits. SRAM cells (bitcells) have the advantageous feature of holding data without a need for refreshing. SRAM bitcells may include different numbers of transistors, and are often accordingly referred to by the number of transistors (i.e., six-transistor (6T) SRAM, eight-transistor (8T) SRAM), and the like. The transistors typically form a data latch for storing a bit. Additional transistors may be added to control the access to the transistors. SRAM bitcells are typically arranged as an array having rows and columns. Typically, each row of the SRAM bitcells is connected to a word-line, which determines whether the current SRAM bitcell is selected or not. Each column of the SRAM bitcells is connected to a bit-line, which is used for storing a bit into the SRAM bitcell or reading from the SRAM bitcell. The SRAM bitcell may be connected to a high voltage power supply (VDD) and also to a complementary low voltage power supply (VSS) to facilitate operation of the SRAM bitcell.

Embedded SRAM has become a very popular storage unit for high-speed communication devices, image processing devices, and other system-on-chip (SOC) products. For a typical SRAM bitcell, one of the most important aspects is the stability of the bitcell. It is therefore desirable to have improvements regarding the stability of SRAM bitcells.

### SUMMARY OF THE INVENTION

Exemplary embodiments will now be described more fully herein with reference to the accompanying drawings, in which exemplary embodiments are shown. Embodiments of the invention provide a mesh circuit for the VSS supply voltage of a SRAM device and also provide a SRAM bitcell design comprising a VSS mesh disposed in two different metal layers.

A first embodiment of the present invention includes a design structure for a SRAM bitcell embodied in a non-transitory machine readable medium for designing, manufacturing, or testing an integrated circuit, the design structure comprising: a VSS mesh disposed in two different metal layers.

A second embodiment of the present invention includes a SRAM device comprising: a plurality of transistors; and a VSS mesh connecting the plurality of transistors, wherein the VSS mesh is disposed in a first metal layer and in a second metal layer.

A third embodiment of the present invention includes a SRAM device comprising: a plurality of transistors; a VSS mesh connecting the plurality of transistors, wherein the VSS mesh comprises: a plurality of horizontal VSS lines in a first metal layer; a plurality of vertical VSS lines in a second metal layer; and a via layer connecting the first metal layer and the second metal layer.

### BRIEF DESCRIPTION OF THE DRAWINGS

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

Features of this invention will be more readily understood from the following detailed description of the various aspects of the invention taken in conjunction with the accompanying drawings in which:

FIG. 1 is a layout showing an embodiment of the present invention in accordance with illustrative embodiments;

FIG. 2 is a schematic representation of a VSS mesh in accordance with illustrative embodiments;

FIG. 3 is an alternative embodiment of the present invention in accordance with illustrative embodiments;

FIG. 4 is a schematic representation in accordance with illustrative embodiments; and

FIG. 5 is a system for implementation in accordance with illustrative embodiments.

### DETAILED DESCRIPTION

Exemplary embodiments will now be described more fully herein with reference to the accompanying drawings, in which exemplary embodiments are shown. Embodiments of the invention provide a mesh circuit for the VSS supply voltage of a SRAM device, and also provide a SRAM bitcell design comprising a VSS mesh disposed in two different metal layers. In the embodiments, one metal layer includes horizontal VSS lines, while another metal layer includes vertical VSS lines. A via layer disposed between the first metal layer and second metal layer connects the two metal layers together. The VSS lines are disposed between the word lines and bit lines, improving the noise stability of the SRAM bitcell.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

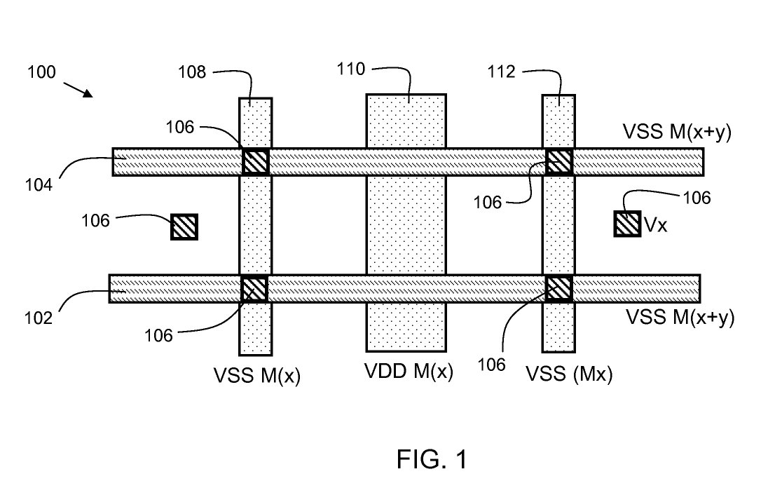

FIG. 1 is a layout 100 showing an embodiment of the present invention. A plurality of vertical VSS lines 108 and 112 are disposed in a first metal layer M(x), and are adjacent to the VDD line 110, which is also in metal layer M(x). A plurality of horizontal VSS lines 102 and 104 are disposed in a second metal layer M(x+y). In some embodiments, the values of x and y are both 1, such that the first metal layer is M1, and the second metal layer is M2. The metal layers are connected by vias 106, which are part of a via layer Vx. While layout 100 shows vertical VSS lines in first metal layer M(x) and horizontal metal lines in second metal layer M(x+y), it is also possible to have embodiments where the vertical VSS lines are in metal layer M(x+y) and the horizontal metal lines are in metal layer M(x). The vias and metal lines may be comprised of copper, tungsten, or other suitable conductor.

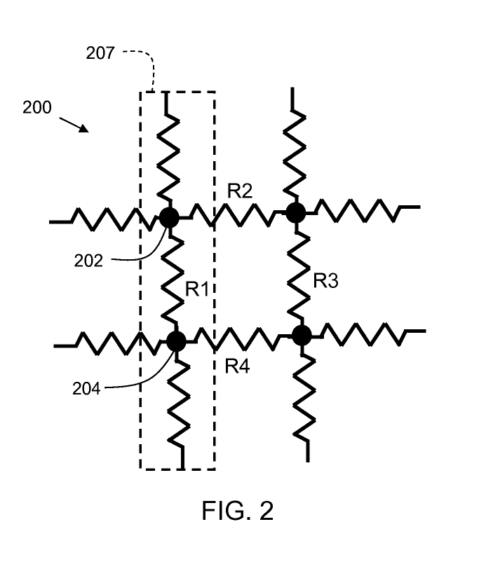

FIG. 2 is a schematic representation of a VSS mesh 200. The VSS mesh 200 serves to lower the resistance between various points within a SRAM circuit. For example, the resistance between point 202 and 204, considering only vertical VSS line 207, is R1. However, considering the VSS mesh 200, the resistance between points 202 and 204 may be approximated as R1 in parallel with (R2+R3+R4), which is less than R1, hence reducing the overall resistance.

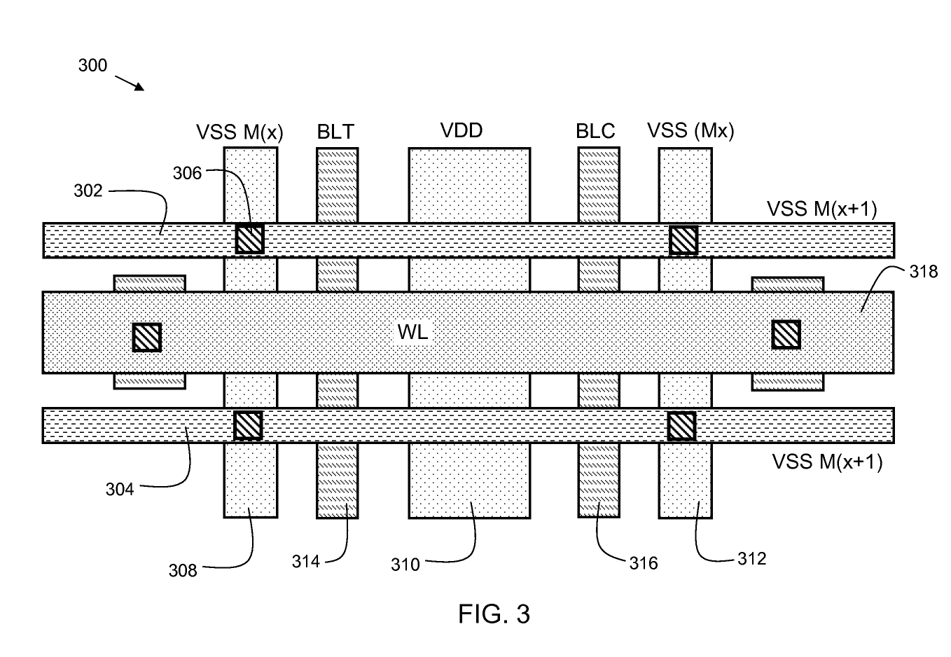

FIG. 3 is an alternative embodiment of the present invention showing layout 300. In this embodiment, vertical VSS lines 308 and 312 are part of metal layer M(x), as is VDD line 310, bit line 308, and complement bit line 316. The vertical VSS lines are disposed adjacent to the bit lines 314 and 316 to provide additional shielding between bit lines. Horizontal VSS lines 302 and 304 are part of a metal layer M(x+1), located above metal layer M(x). Horizontal VSS lines 302 and 304 are disposed adjacent to word line 318, which is also at metal layer M(x+1). Hence, VSS lines 302 and 304 serve to prevent noise coupling between word lines in a SRAM array. The vertical VSS lines 308 and 312 are connected to the horizontal VSS lines 302 and 304 by vias 306, which are part of a via layer Vx. While layout 300 shows vertical VSS lines in first metal layer M(x) and horizontal metal lines in second metal layer M(x+1), it is also possible to have embodiments where the vertical VSS lines are in metal layer M(x+1) and the horizontal metal lines are in metal layer M(x). The decision on which metal layer to use for the horizontal and vertical VSS lines may depend on which metal layer and orientation is used for the word lines and bit lines of the SRAM array. The vias and metal lines may be comprised of copper, tungsten, or other suitable conductor.

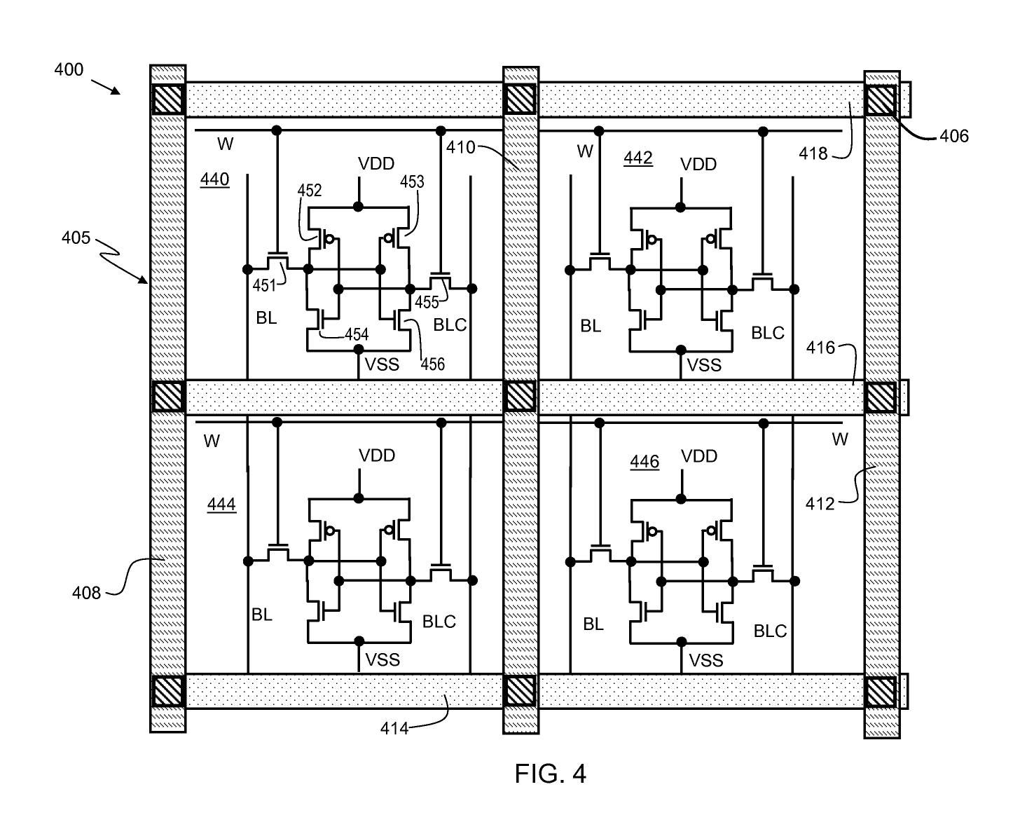

FIG. 4 is a schematic representation 400 of an embodiment of the present invention, as overlaid with the two metal layers that make up a VSS mesh 405. Within schematic representation 400, four SRAM bitcells are shown, indicated as references 440, 442, 444, and 446. As indicated for bitcell 440, each bit cell comprises 6 transistors (451-456) arranged in a 6T SRAM configuration. Other embodiments may include other SRAM configurations, such as an 8T, 10T, or 4T SRAM configuration and may include a different number of transistors. The VSS mesh 405 is comprised of vertical VSS lines 408, 410, and 412 in a first metal layer, and horizontal VSS lines 414, 416, and 418 in a second metal layer. The horizontal and vertical VSS lines are electrically connected together with vias (shown generally as 406) which are part of a via layer disposed between the two metal layers. In some embodiments, the first metal layer is M1 and the second metal layer is M2. Each bitcell (440, 442, 444, and 446) is bounded by the VSS mesh 405. Hence, voltage loss across a large SRAM array is reduced due to the mesh circuit, and noise shielding is improved by disposing the lines of the mesh circuit adjacent to bit lines and word lines. Thus, the overall reliability of SRAM arrays in accordance with embodiments of the present invention is improved.

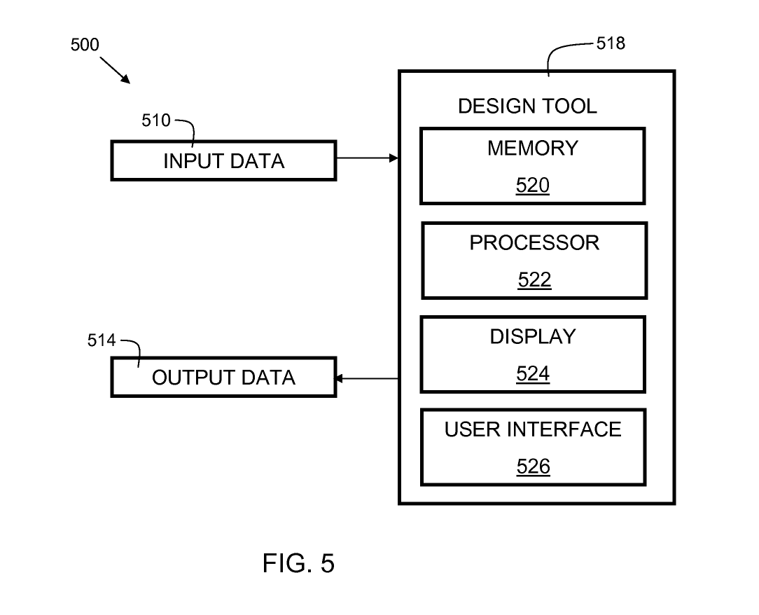

FIG. 5 is a system 500 for implementation in accordance with embodiments of the present invention. System 500 includes a design tool 518. Design tool 518 may be a computer comprising memory 520, and a processor 522 which is configured to read and write memory 520. In some embodiments, multiple processors or cores may be used. The memory 520 may be a non-transitory computer-readable medium, such as flash, ROM, non-volatile static ram, or other non-transitory memory. The memory 520 contains instructions that, when executed by processor 522, control the various subsystems to operate system 500. Design tool 518 may also include a display 524 and a user interface 526 for interacting with the system 500. The user interface 526 may include a keyboard, touch screen, mouse, or the like.

The design tool 518 may receive input data 510. Input data 510 may include a design structure, which may include a representation of metallization layers formed into a VSS mesh circuit. The design structure may be embodied in a non-transitory machine readable medium for designing, manufacturing, or testing an integrated circuit, such as memory 520. Hence, the non-transitory machine readable medium may embody a design structure for designing, manufacturing, or testing a design for an integrated circuit, the design structure configured to generate a representation of the integrated circuit in a format perceptible by humans when read by a machine. The design structure may be a logical simulation design structure generated and processed by a design process to produce a logically equivalent functional representation of a hardware device. The design structure may also, or alternatively, include data and/or program instructions that when processed by design tool 518, generate a functional representation of the physical structure of a hardware device. The input data 510 may include hardware-description language (HDL) design entities or other data structures conforming to and/or compatible with lower-level HDL design languages such as Verilog and VHDL, and/or higher level design languages such as C, C++, or Python. Embodiments of the present invention may further include a computer program product embodied in a non-transitory computer-readable medium. The product may further include a design structure for implementing a VSS mesh in a SRAM array.

The design tool 518 may generate output data 514. The generated output data 514 may be in a stream format indicative of a SRAM design including a VSS mesh circuit. The output data may reside in a storage medium in a data format used for the exchange of layout data of integrated circuits (e.g. information stored in a GDSII (GDS2), GL1, OASIS, or any other suitable format for storing such design structures). Output data 514 may include information such as, for example, test data files, design content files, manufacturing data, layout parameters, wires, levels of metal, vias, shapes, data for routing through the manufacturing line, and any other data required by a semiconductor manufacturer to produce embodiments of the present invention.

In various embodiments, design tool 518 can be provided and configured to create the datasets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A design structure for a static random access memory (SRAM) bitcell embodied in a non-transitory machine readable medium for designing, manufacturing, or testing an integrated circuit, the design structure comprising:
a VSS mesh disposed in two different metal layers;
wherein the VSS mesh comprises:
a plurality of horizontal VSS lines in a first metal layer;
a plurality of vertical VSS lines in a second metal layer; and
a via layer connecting the first metal layer and the second metal layer.
wherein each of the plurality of vertical VSS lines are disposed adjacent to a word line, wherein the word line is disposed in the second metal layer;
wherein each of the plurality of horizontal VSS lines are disposed adjacent to a bit line, wherein the bit line is disposed in the first metal layer.

2. (canceled)

3. The design structure of claim 1, wherein the first metal layer is M1, and the second metal layer is M2.

4. The design structure of claim 1, wherein the first metal layer is M2, and the second metal layer is M1.

5-8. (canceled)

9. The design structure of claim 1, wherein the VSS mesh is connected to a plurality of transistors arranged in a 6T configuration.

10. A static random access memory (SRAM) device comprising:
a plurality of transistors; and
a VSS mesh connecting the plurality of transistors;
wherein the VSS mesh comprises:
a plurality of horizontal VSS lines in a first metal layer;
a plurality of vertical VSS lines in a second metal layer; and
a via layer connecting the first metal layer and the second metal layer
wherein each of the plurality of vertical VSS lines are disposed adjacent to a word line,
wherein the word line is disposed in the second metal layer;
wherein each of the plurality of horizontal VSS lines are disposed adjacent to a bit line,
wherein the bit line is disposed in the first metal layer.

11. (canceled)

12. The SRAM device of claim 10, wherein the first metal layer is M1, and the second metal layer is M2.

13. The SRAM device of claim 10, wherein the first metal layer is M2, and the second metal layer is M1.

14-17. (canceled)

18. A static random access memory (SRAM) device comprising:
a plurality of transistors;
a VSS mesh connecting the plurality of transistors, wherein the VSS mesh comprises:
a plurality of horizontal VSS lines in a first metal layer;
a plurality of vertical VSS lines in a second metal layer; and
a via layer connecting the first metal layer and the second metal layer, and wherein:
the plurality of horizontal VSS lines, the plurality of vertical VSS lines, and the via layer are comprised of copper;
wherein each of the plurality of horizontal VSS lines are disposed adjacent to a word line, wherein the word line is in the first metal layer; and
wherein each of the plurality of vertical VSS lines are disposed adjacent to a bit line, wherein the bit line is disposed in the second metal layer.

19-20. (canceled)
